(19) United States
(12) Patent Application Publication
(10) Pub. No.: US 2006/0220023 A1
(43) Pub. Date: Oct. 5, 2006

(54) Thin-film device

(76) Inventors: Randy Hoffman, Corvallis, OR (US); Gregory Herman, Albany, OR (US); Curt Nelson, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/072,947

(22) Filed: Mar. 3, 2005

(51) Int. Cl. H01L 29/04

(52) U.S. Cl. 257/72

(57) ABSTRACT

Embodiments of methods, apparatuses, devices and systems associated with a thin-film device are disclosed.

### BACKGROUND

Electronic devices, such as integrated circuits, solar cells, or electronic displays, for example, may be comprised of one or more electrical devices, such as one or more thin-film transistors (TFTs). Methods or materials utilized to form electrical devices such as these may vary, and one or more of these methods or materials may have particular disadvantages. For example, use of such methods or materials may be time-consuming or expensive, may involve the use of high temperature processing, or may not produce devices having the desired characteristics.

### BRIEF DESCRIPTION OF THE DRAWINGS

Subject matter is particularly pointed out and distinctly claimed in the concluding portion of the specification. The claimed subject matter, however, both as to organization and method of operation, together with objects, features, and advantages thereof, may best be understood by reference of the following detailed description when read with the accompanying drawings in which:

FIG. 1 is a depiction of an embodiment of a thin-film transistor structure having laser annealed active regions;

FIG. 2 is a depiction of an embodiment such as a thin-film transistor;

FIG. 3 is a depiction of a simplified top view of the embodiment of FIG. 2; and

FIG. 4 is a depiction of an embodiment having adjacent thin-film transistor structures.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, methods, procedures, components and circuits that would be understood by one of ordinary skill have not been described in detail so as not to obscure claimed subject matter.

Electronic devices, such as semiconductor devices, display devices, nanotechnology devices, conductive devices, and dielectric devices, for example, may comprise one or more electronic components. The one or more electronic components may comprise one or more thin-film components, which may be comprised of one or more thin films. In the context of this application the term or means a sentential connective that forms a complex sentence which is true when at least one of its constituent sentences is true. In this context, the term thin film refers to a layer of one or more materials formed to a thickness, such that surface properties of the one or more materials may be observed, and these properties may vary from bulk material properties. Thin films may additionally be referred to as component layers, and one or more component layers may comprise one or more layers of material, which may be referred to as material layers, for example. The one or more material or component layers may have electrical or chemical properties, such as conductivity, chemical interface properties, charge flow, or processability. The one or more material or component layers may additionally be patterned, for example. The one or more material or component layers, in combination with one or more other material or component layers may form one or more electrical components, such as thin-film transistors (TFTs), capacitors, diodes, resistors, photovoltaic cells, insulators, conductors, optically active components, or the like. Components such as TFTs, in particular, may, for example, be utilized in components including smart packages and display components including, for example, radio frequency identification (RFID) tags and electroluminescent and a liquid crystal displays (LCD), such as active matrix liquid crystal display (AMLCD) devices, for example.

At least as part of the fabrication process of electronic components, such as thin-film transistors, one or more layers of material may be formed at least as part of one or more of the component layers, such as by forming at least a portion of an electrode, including: source, drain, or gate electrodes; a channel layer; or a dielectric layer. These one or more layers of material may be formed on or over a substrate, for example.

In at least one embodiment, one or more processes utilized may comprise one or more low temperature processes. In this context, low temperature processes or processing refers to one or more processes that may be performed at relatively low temperatures as compared to one or more other processes. For example, processes that may be utilized to form material layers of a TFT, may be performed at particular temperatures, such as temperatures equal to or less than approximately 300 degrees Celsius, including processes performed at temperatures equal to or less than approximately 100 degrees Celsius. It should be noted that particular temperature ranges may depend in part on the type of materials or processes utilized, and claimed subject matter is not limited in this respect. In at least one embodiment, utilization of low temperature processes may provide the capability to utilize materials that would not be suitable for use in non-low temperature processes, for example. Additionally, use of low temperature materials or processes may result in the formation of a component, such as a TFT, having improved mechanical flexibility or resistance to mechanical failure such as by delamination or cracking, as compared to components formed by use of non-low temperature processes, and may additionally result in the formation of a device having other properties, as will be explained in more detail later. However, it is worthwhile to note that claimed subject matter is not limited in this respect.

One or more processes or materials, such as low temperature processes or materials may be utilized to form one or more material or component layers of a component. For example, one or more temperature sensitive materials, such as temperature sensitive substrate materials, channel layer materials or dielectric layer materials may be utilized, and this may include materials that may have characteristics such as flexibility, for example, or may include materials not suitable for use in non-low temperature processes, for example. Additionally, one or more low temperature processes, such as selective annealing; vacuum deposition processes including RF (radio frequency) sputtering, DC sputtering, DC-pulsed sputtering, or reactive sputtering, wherein the substrate may be unheated or maintained at a suitably low temperature; atomic layer deposition (ALD); or evaporation processes, including thermal or electron-beam evaporation, for example, may be utilized in at least one embodiment.

Furthermore, electrical components, such as TFTs, for example, may be at least partially formed by laser annealing or processing. In this context laser annealing refers to locally exposing a selected portion of a suitable material to one or more laser beams to alter at least one or more properties of the suitable material. Laser annealing in this context, as opposed to thermal annealing of the entire substrate, may obviate the need for subtractive processing or selective removal, such as by photolithography and the like, of portions of the suitable material that may otherwise hinder device to device electrical isolation for adjacent thin-film transistors. In addition, laser annealing may, under some circumstances, be performed at lower temperatures than thermal annealing, which may allow use of heat sensitive substrates that may otherwise be damaged by thermal annealing. Furthermore, laser annealing may allow thermal treatment to higher temperatures than may be appropriate for use with heat sensitive substrates under other circumstances due to the controlled thermal transient from the laser, the localized nature of the laser spot, or the thermal conduction pathways from the localized laser spot, for example. It should of course be noted that claimed subject matter is not limited in this regard.

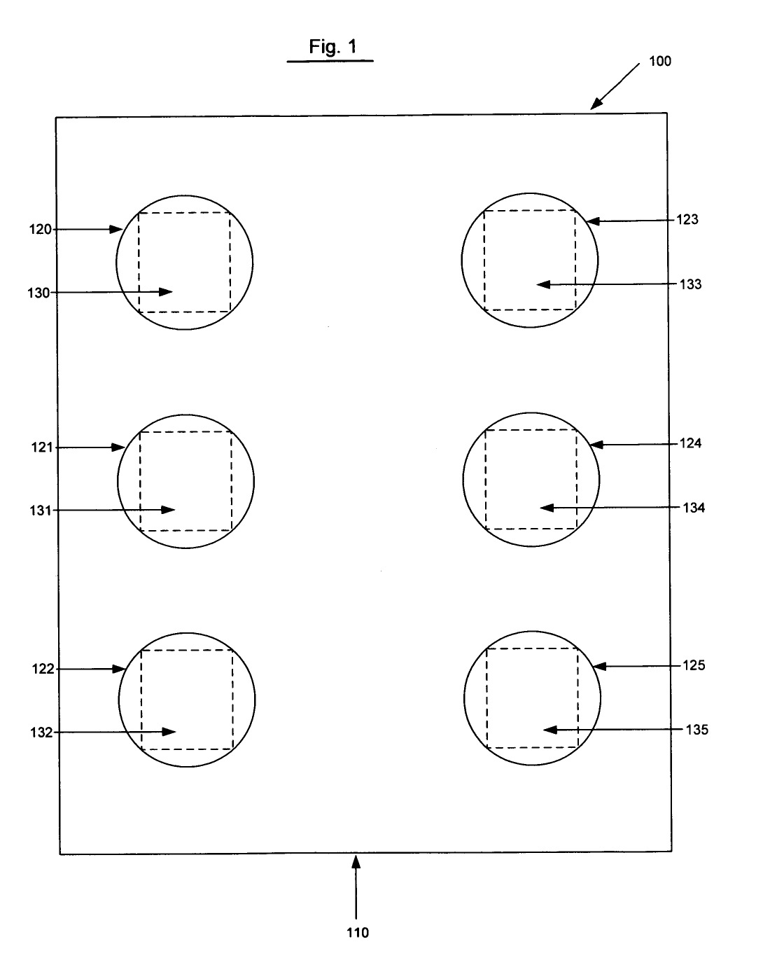

FIG. 1 is a depiction of an embodiment 100 of a thin-film transistor structure having laser annealed active regions. With regard to FIG. 1, embodiment 100 may include a substrate 110. Substrate 110 may comprise an organic or an inorganic material, for example. In addition, embodiment 100 may include laser annealed regions 120, 121, 122, 123, 124, and 125. It should be noted that claimed subject matter is not limited to any particular number of laser annealed regions. In this context, laser annealed regions 120, 121, 122, 123, 124, and 125, may be formed by selectively exposing a region of a material, such as an oxide material, to one or more laser beams or laser pulses. The oxide material may comprise any of a number of suitable materials such as zinc oxide, tin oxide, indium oxide, cadmium oxide, gallium oxide, or combinations thereof, including zinc tin oxide, zinc indium oxide, or combinations thereof, to name but a few examples. Furthermore, embodiment 100 may include active regions 130, 131, 132, 133, 134, and 135. Active regions 130, 131, 132, 133, 134, and 135 may be formed through a combination of laser annealed regions 120, 121, 122, 123, 124 and 125, and optionally including other semiconductor layers, which when combined with other thin-film structures or layers may form a transistor or a portion of a transistor, such as a channel region, for example. It should be noted that claimed subject matter is not limited in this regard.

With regard to FIG. 1, substrate 110 may comprise one or more types of plastic or one or more organic substrate materials, such as polyimides (PI), including Kapton®; polyethylene terephthalates (PET); polyethersulfones (P ES); polyetherimides (PEI); polycarbonates (PC); polyethylenenaphthalates (PEN); acrylics, including acrylates and methacrylates, such as polymethylmethacrylates (PMMA); or combinations thereof, but claimed subject matter is not so limited. Additionally, substrate 110 may also comprise one or more inorganic materials, including silicon, silicon dioxide, one or more types of glass, quartz, sapphire, stainless steel and metal foils, including foils of aluminum or copper, or a variety of other suitable materials, for example, but claimed subject matter is not so limited. Additionally, in at least one embodiment, wherein a substrate material is substantially comprised of one or more metals, an insulator layer may be utilized in addition to the one or more metals to form the substrate. A choice of substrate materials may determine certain characteristics or tolerances that may influence the available semiconductor fabrication processes that are suitable for use with a particular substrate material. For example, organic substrate materials may be more sensitive to heat and as such may be more suitable for use with lower temperature processes than those that may be suitable for use with inorganic substrates under certain circumstances. Choice of substrate material may depend on a variety of factors including, but not limited to, heat sensitivity, cost, flexibility, durability, resistance to failure, surface morphology, chemical stability, optical transparency, barrier properties, etc. and of course it should be noted that claimed subject matter is not limited in this regard.

In addition, the oxide material may further comprise various combinations of the above listed oxides with other oxides such as lead oxide, copper oxide, silver oxide, or antimony oxide, to name but a few examples. Of course it should be noted that claimed subject matter is not limited in this regard. The laser beams or laser pulses may be generated by a UV excimer laser generating laser beams or laser pulses having an approximate range of 193-337 nanometers in wavelength, such as approximately 248 nanometers in wavelength, for example, though other lasers having different wavelength ranges may be employed, and claimed subject matter is not limited in this regard. Laser treatment parameters, such as fluence, shot count, scan speed, duty cycle, etc. may be varied to achieve desired electrical, physical, or chemical properties in the laser annealed regions, and again claimed subject matter is not limited in this regard. For example, the UV excimer laser may be employed with a fluence of approximately 5 to 600 millijoules per square centimeter, and a shot count of approximately 10 to 5000, to name but a few possible laser treatment parameters. Again, however, it should be noted that the above laser treatment parameters are provided as merely examples and that claimed subject matter is not so limited.

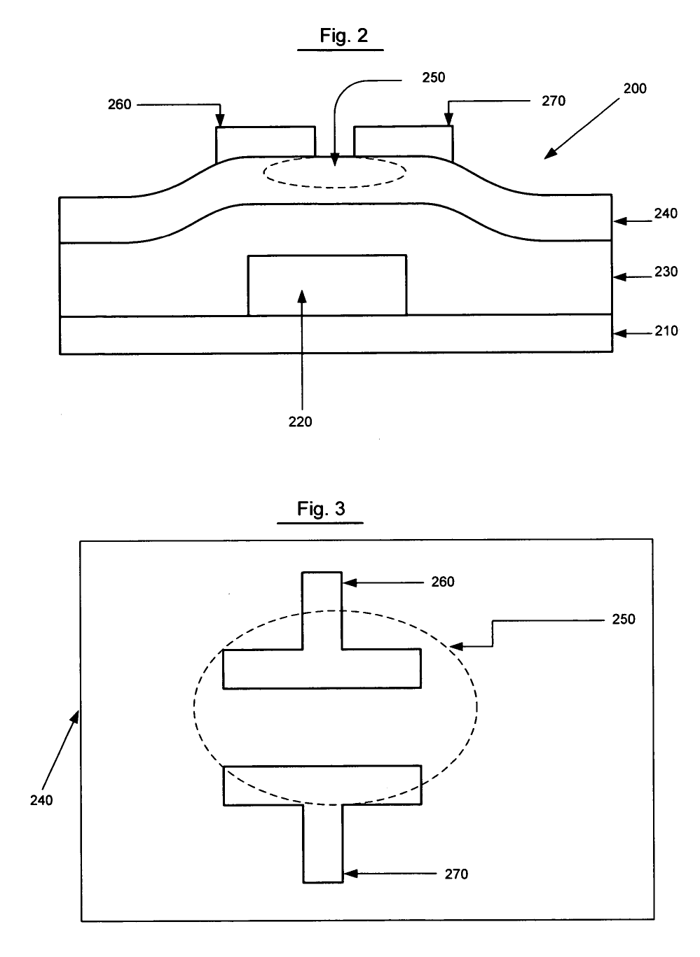

FIG. 2 is a diagram of an embodiment 200, such as thin film transistor, for example, that may include portions that may correspond to one of the active regions of FIG. 1. With regard to FIG. 2, embodiment 200 may comprise a first layer 210, such as a substrate, for example. Embodiment 200 may further comprise a second layer 220. Second layer 220 may comprise a gate electrode layer, for example. Embodiment 200 may also include third layer 230, such as a gate dielectric layer which may comprise silicon dioxide or other materials. Embodiment 200 may further include an un-patterned oxide layer 240. Un-patterned oxide layer 240 may comprise a blanket coated oxide layer deposited using a vacuum deposition process. In this context, blanket coated may refer to any un-patterned deposition such as one that may cover a relatively small portion of a substrate up to and including a deposition that may cover a relatively large portion of a substrate, which may under some circumstances include an entire substrate, depending on various factors, for example. In the context of embodiment 200, a blanket coated oxide layer may correspond to an actual surface area on the order of centimeters, for example, though again it should be noted that claimed subject matter is not so limited. In addition, blanket coated or un-patterned oxide layer may comprise a layer such that, as deposited and without further treatment, the area of the blanket coated or un-patterned oxide layer may be substantially larger than that of a single thin-film transistor or other semiconductor component, for example. With regard to un-patterned oxide layer 240, vacuum deposition processes may include, but are in no way limited to, RF (radio frequency) sputtering, DC sputtering, DC-pulsed sputtering, or reactive sputtering, for example, though again claimed subject matter is not so limited. Un-patterned oxide layer 240 may comprise an oxide material such as zinc oxide, tin oxide, indium oxide, cadmium oxide, gallium oxide, or combinations thereof, including zinc tin oxide, zinc indium oxide, or combinations thereof, to name but a few examples.

In embodiment 200 un-patterned oxide layer 240 may have a selectively annealed active region 250, which may, within the structure of embodiment 200 and along with other layers or structures depicted or not shown, function as a channel region for a transistor, such as a thin-film transistor for example. Selectively annealed active region 250 may be formed by laser annealing a selected portion of un-patterned oxide layer 240. In this context laser annealing may comprise selectively exposing the selected portion of un-patterned oxide later 240 to at least one or more laser pulses or laser beams. The one or more laser pulses or laser beams may, as discussed above, be generated by a UV excimer laser generating laser beams or laser pulses at approximately 193-337 nanometers in wavelength, though other types of lasers which may or may not have different wavelength ranges may be employed, such as solid-state visible or near-IR lasers with wavelengths of 355-1064 nanometers, far-IR lasers with wavelengths of 9.6-10.6 um, or fiber lasers with wavelengths of 775-2100 nm, to name but a few examples, and it should be noted that claimed subject matter is not limited in this regard. Laser treatment parameters, such as fluence, shot count, pulse length, firing frequency, scan speed, duty cycle, etc. may be varied to achieve desired electrical, physical, or chemical properties in the laser annealed regions, and again claimed subject matter is not limited in this regard. Embodiment 200 may further include a source electrode 260 and a drain electrode 270. Although other materials and deposition processes may be used, source electrode 260 may be formed by RF sputtering indium-tin oxide (ITO) above or onto un-patterned oxide layer 240, or gate insulator layer 230, for example, although claimed subject matter is not so limited. Likewise, drain electrode 270 may be formed by RF sputtering indium-tin oxide above or onto un-patterned oxide layer 240, or insulator layer 230, for example. Source electrodes 260 and drain electrode 270 may have a thickness that under some circumstances may be in a range of approximately 50 to 500 nm, although it should be noted that claimed subject matter is not limited in this regard.

First layer 210 may comprise one or more types of plastic or one or more organic substrate materials, such as polyimides (PI), including Kapton; polyethylene terephthalates (PET); polyethersulfones (PES); polyetherimides (PEI); polycarbonates (PC); polyethylenenaphthalates (PEN); acrylics, including acrylates, and methacrylates, such as polymethylmethacrylates (PMMA); or combinations thereof, but it should be noted that claimed subject matter is not so limited. Additionally, first layer 210 may additionally comprise one or more inorganic materials, including silicon, silicon dioxide, one or more types of glass, stainless steel and metal foils, including foils of aluminum and copper, for example, but again claimed subject matter is not so limited. Additionally, in at least one embodiment, wherein a first layer 210 may comprise a substrate material that substantially comprises one or more metals, an insulator layer (not shown) may be utilized in addition to the one or more metals to form a first layer 210, for example. Second layer 220 may comprise a metal such as Al, Ag, In, Sn, Zn, Ti, Cr, Mo, Au, Pd, Pt, Cu, W, Ni or combinations thereof. It should be noted that claimed subject matter is not limited in this regard. First layer 220 may under some circumstances have a thickness that may be in a range of approximately 50 to 500 nm, although it should be noted that claimed subject matter is not limited in this regard. In addition, second layer 220 may comprise other conductive materials, such as other metals or doped oxide semiconductors, such as n-type doped zinc oxide, indium oxide, or tin oxide, including indium tin oxide (ITO), to name but a few examples, though other materials may be used to form a gate layer and will be understood by one of ordinary skill.

Additionally third layer 230 may comprise other materials such as inorganic dielectrics such as zirconium oxide, tantalum oxide, yttrium oxide, lanthanum oxide, silicon oxide, aluminum oxide, hafnium oxide, barium zirconate titanate, barium strontium titanate, silicon nitride, or silicon oxynitride, to name but a few examples. In addition, third layer 230 may comprise organic dielectrics such as curable monomers, including UV curable acrylic monomers, UV curable monomers, thermal curable monomers; acrylic polymers; polymer solutions such as melted polymers or oligomer solutions; poly methyl methacrylate, poly vinylphenol; benzocyclobutene; or one or more polyimides, to name but a few examples. In addition, third layer 230 may have a thickness that may under some circumstance be in a range of approximately 20 to 1000 nm, although it should be noted that claimed subject matter is not limited in this regard. In addition, third layer 230 may under some circumstance comprise multiple sub-layers, including one or more inorganic dielectric or organic dielectric layers, though other materials may be used to form a gate insulator layer and will be understood by one of ordinary skill and claimed subject matter is not limited in this regard. Un-patterned oxide layer 240 may have a thickness which under some circumstances may be in a range of approximately 10 to 500 nm, although it should be noted that claimed subject matter is not limited in this regard. For example, un-patterned oxide layer 240 may comprise zinc tin oxide with a zinc:tin atomic ratio in the range of approximately 1:1 to approximately 4:1, RF sputtered above or onto gate insulator layer 230, to a thickness of approximately 50 nm, though this is just an example and claimed subject matter is not so limited. By way of example, RF sputtering may be carried out with an unheated substrate, examples of which are discussed above, at 100 W RF (for an approximately 3-inch diameter target), in an approximately 90% argon and 10% oxygen environment at 5 mTorr. It should be noted that the above details of an RF sputtering process are provided merely for illustration and claimed subject matter is not limited in this regard. Furthermore, the oxide material of un-patterned oxide layer 240 may further comprise combinations of the above listed oxides with other oxides such as lead oxide, copper oxide, silver oxide, or antimony oxide for example, though other materials may be suitable as well and claimed subject matter is not limited in this regard. In addition, source electrode 260 and drain electrode 270 may also comprise other materials such as other doped oxide semiconductors, such as n-type doped zinc oxide, indium oxide, or tin oxide, or metals, such as Al, Ag, In, Sn, Zn, Ti, Cr, Mo, Au, Pd, Pt, Cu, W, Ni, or combinations thereof, to name but a few examples and again claimed subject matter is not so limited.

FIG. 3 is a depiction of a simplified top view of embodiment 200. With regard to FIG. 3, un-patterned oxide layer 240, as discussed above with regard to FIG. 2, may have been formed over gate insulator layer 230 (shown in FIG. 2), by a vacuum deposition process, for example. Active region 250 may be formed by selectively annealing a selected portion of un-patterned oxide layer 240. Again, selectively annealing a selected portion of un-patterned oxide layer may comprise laser annealing a selected portion of un-patterned oxide layer 240, such as by exposing the selected portion to one or more laser beams or laser pulses, for example. As discussed above, the one or more laser beams or pulses may be generated by a UV excimer laser or other lasers, for example. Again, it should be noted that claimed subject matter is not so limited. As discussed above, laser treatment parameters can be varied in a number of ways to produce desired physical, electrical, or chemical properties in the selected portion of un-patterned oxide layer 240, for example. Desired properties for active region 250 may comprise a range for transistor turn-on voltage, a range of channel carrier concentration, a range of transistor channel mobility, and a maximum acceptable defect density, for example, although claimed subject matter is not so limited. As discussed above, embodiment 200 may additionally have a source, such as source electrode 260, along with a drain, such as drain electrode 270. As shown in FIG. 3 there may be a gap between source electrode 260 and drain electrode 270. Active region 250 may be positioned at least partially within the gap between source electrode 260 and drain electrode 270. In this context, active region 250 may, in combination with source electrode 260, drain electrode 270 or other layers or structures, function as a channel region such that the combination may function as a transistor, such as a thin-film transistor, for example.

Though embodiment 200 has been described above with regard to a particular structure it should be noted that the thin-film transistors may be of any type or structure, including but not limited to, horizontal, vertical, coplanar electrode, staggered electrode, top-gate, bottom-gate, single-gate, and double-gate, to name but a few. In this context, a coplanar electrode configuration may mean a transistor structure where the source and drain electrodes are positioned on the same side of the channel layer as the gate electrode. In this context, a staggered electrode configuration may mean a transistor structure where the source and drain electrodes are positioned on the opposite side of the channel layer as the gate electrode.

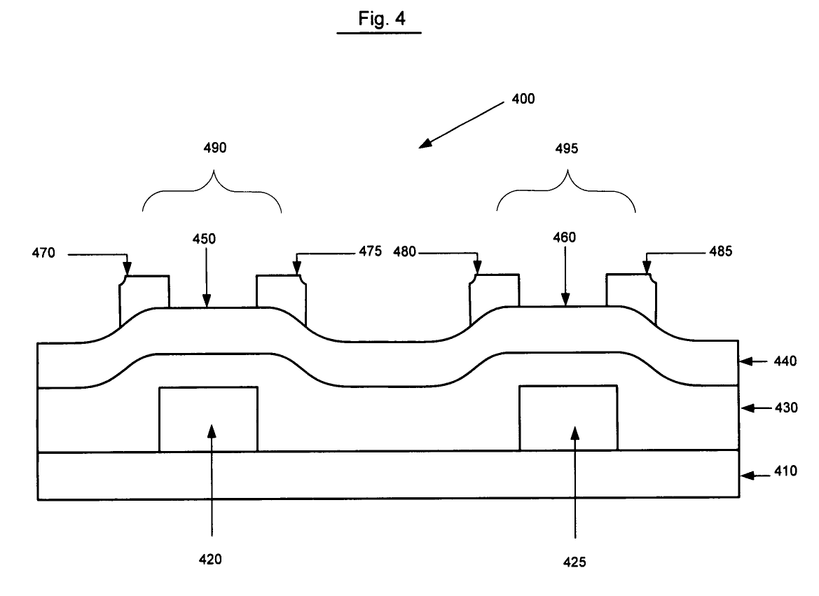

FIG. 4 is a depiction of an embodiment 400. With regard to FIG. 4, embodiment 400 may include a first layer 410, such as a substrate layer. In this context a substrate layer may, for example, comprise one or more types of plastic or one or more organic substrate materials. Embodiment 400 may further comprise a first gate electrode 420 and a second gate electrode 425. Embodiment 400 may further include a third layer 430, such as a gate insulator layer, which may comprise silicon dioxide or other materials such as inorganic dielectrics such as zirconium oxide, tantalum oxide, yttrium oxide, lanthanum oxide, silicon oxide, aluminum oxide, hafnium oxide, barium zirconate titanate, barium strontium titanate, silicon nitride, or silicon oxynitride, as just a few examples.

Embodiment 400 may further include an un-patterned or blanket coated oxide layer 440. In this context, blanket coated may refer to any un-patterned deposition of a material or materials such as a deposition that may cover a relatively small portion of a substrate and up to and including a deposition that may cover a relatively large portion of a substrate, depending on various factors, for example. In the context of embodiment 400, a blanket coated oxide layer may correspond to an actual surface area on the order of centimeters, for example, though again it should be noted that claimed subject matter is not so limited. In addition, un-patterned or blanket coated may mean that the as deposited layer is such that without further treatment or processing the area of the as deposited layer may be substantially larger than that of a single thin-film transistor or other semiconductor component, for example. Un-patterned oxide layer 440 may comprise an oxide layer deposited using a vacuum deposition process. Un-patterned oxide layer 440 may comprise an oxide material such as zinc oxide, tin oxide, indium oxide, cadmium oxide, gallium oxide, or combinations thereof, including zinc tin oxide, zinc indium oxide, to name but a few examples. For example, un-patterned oxide layer 440 may comprise zinc tin oxide with zinc:tin atomic ratio in the range of approximately 1:1 to approximately 4:1, RF sputtered above or onto gate insulator layer 430, though it should be noted that this is just an example and claimed subject matter is not so limited. In addition, the RF sputtering may be carried out with a heated or unheated substrate, examples of which are discussed above, at 100 W RF (for an approximately 3-inch diameter target), in an approximately 90% argon and 10% oxygen environment or at approximately 5 mTorr, for example. Again, the details of the sputtering process described above are provided merely for illustration and are in no way intended to limit claimed subject matter.

In embodiment 400, un-patterned oxide layer 440 may further comprise a first selectively annealed active region 450 and a second selectively annealed active region 460. As discussed further below first selectively annealed active region 450 and second selectively annealed active region 460 may, within the overall structure and in connection with other layers or structures of embodiment 400, function as a first channel region and a second channel region for a first transistor and a second transistor, respectively, such as a first and a second thin-film transistor, for example. First selectively annealed active region 450 and second selectively annealed active region 460 may be formed by laser annealing a respective first selected portion and a second selected portion of un-patterned oxide layer 440. In this context laser annealing may comprise selectively exposing the first and second selected portions of un-patterned oxide layer 440 to at least one or more laser pulses. The at least one or more laser pulses may, as discussed above, be generated by a UV excimer laser. The UV excimer laser may, for example, be operable to generate laser beams or laser pulses having an approximate wavelength range of 193-337 nanometers, such as having a wavelength of approximately 248 nanometers. As discussed above, it should be noted that other types of lasers which may or may not have different wavelength ranges or power ranges may be employed, and claimed subject matter is not limited in this regard. Laser treatment parameters, such as fluence, shot count, pulse length, firing frequency, scan speed, duty cycle, etc. may be varied to achieve desired electrical, physical, or chemical properties in the laser annealed regions, and again claimed subject matter is not limited in this regard.

Embodiment 400 may further include a first source electrode 470 and a first drain electrode 475. Although other materials and deposition processes may be used, first source electrode 470 may be formed by RF sputtering indium-tin oxide above or onto un-patterned oxide layer 440 or gate insulator layer 430, for example. Likewise, first drain electrode 475 may be formed by RF sputtering indium-tin oxide above or onto un-patterned oxide layer 440 or gate insulator layer 430, for example. Again, different materials or deposition processes, such as other sputtering processes, thermal evaporation processes, e-beam evaporation processes or chemical vapor deposition processes, for example, may be used to form first source electrode 470 and first drain electrode 475, and claimed subject matter is not limited to the particular processes and materials described above. Embodiment 400 may further include a second source electrode 480 and a second drain electrode 485. Although other materials and deposition processes may be used, second source electrode 480 may be formed by RF sputtering indium-tin oxide above or onto un-patterned oxide layer 440 or gate insulator layer 430, for example. Second source electrode 480 and second drain electrode 485 may be formed by RF sputtering indium-tin oxide above or onto un-patterned oxide layer 440 or gate insulator layer 430, for example. Again different materials or deposition processes may be used to form second source electrode 480 and second drain electrode 485, and claimed subject matter is not limited in this regard.

In embodiment 400 first gate electrode 420, first source electrode 470, first drain electrode 475, gate insulator layer 430, and first active region 450 may function as a first transistor 490, such that first active region 450 may function as a first channel region. Likewise, second gate electrode 425, second source electrode 480, second drain electrode 485, gate insulator layer 430, and second active region 460 may function as a second transistor 495, such that second active region 460 may function as a second channel region. Embodiment 400 may achieve effective electrical isolation between first transistor 490 and second transistor 495 without requiring a subtractive processing of non-annealed portions of un-patterned oxide layer 440, such as by employing a photolithography process or the like, for example. For certain materials, such as zinc oxide, indium oxide, tin oxide, cadmium oxide, gallium oxide, or combinations thereof, including zinc tin oxide, zinc indium oxide, or other combinations thereof, to name but a few examples, and for appropriately selected deposition technique and conditions, the non-annealed portions of the un-patterned oxide layer 440 may exhibit certain properties, such as a relatively large and positive (in the case of n-channel transistor) turn-on voltage, relatively low mobility, relatively low carrier concentration, or relatively high trap density, such that the non-annealed portion of the un-patterned oxide layer may exhibit relatively low conductivity resulting in relatively minimal leakage between adjacent transistor structures 490 and 495. When materials such as those mentioned above or below are used to form un-patterned oxide layer 440, the properties of the non-annealed material may hinder device to device current leakage between adjacent transistors, such as first transistor 490 and second transistor 495. However, as discussed above, any selectively annealed portion, such as first active region 450 and second active region 460, of un-patterned oxide layer 440, may, due having been selectively annealed, have properties such that the selectively annealed portion may function as a part, such as a channel region, of a thin-film transistor, for example.

For example, an un-patterned oxide layer, such as un-patterned oxide layer 440, when comprising zinc oxide, tin oxide, indium oxide, cadmium oxide, gallium oxide, or combinations thereof, including zinc tin oxide, zinc indium oxide, or other combinations thereof, which may have been RF sputtered onto a gate insulating layer, such as gate insulating layer 430, may have properties such as relatively low mobility, relatively high trap density and relatively large, and in the case of an n-channel transistor, positive turn-on voltage such that un-patterned oxide layer 440 may not effectively pass current laterally between adjacent contacts, such as adjacent transistor sources and drains, for example. However, active regions 450 and 460, having been selectively annealed by exposure to one or more laser beams or pulses generated by an UV excimer laser, or other lasers, for example, in a laser treatment process such as, but not limited to, those described above or below may exhibit much different properties such as a relatively smaller turn-on voltage, a relatively lower trap density, and a relatively higher mobility such that active regions 450 and 460 may have suitable properties for functioning as channel regions in first transistor 490 and second transistor 495 respectively.

In addition to the materials described above, first layer 410 may comprise materials, such as polyimides (PI), including Kapton; polyethylene terephthalates (PET); polyethersulfones (PES); polyetherimides (PEI); polycarbonates (PC); polyethylenenaphthalates (PEN); acrylics, including acrylates, and methacrylates, such as polymethylmethacrylates (PMMA); or combinations thereof, but it should be noted that claimed subject matter is not so limited. Additionally, first layer 410 may comprise one or more inorganic materials, including silicon, silicon dioxide, one or more types of glass, stainless steel and metal foils, including foils of aluminum and copper, for example, but claimed subject matter is not so limited. Additionally, in at least one embodiment, wherein a first layer 410 may comprise a substrate material that substantially comprises one or more metals, an insulator layer (not shown) may be utilized in addition to the one or more metals to form a first layer 410, for example. In addition to the materials listed above, first gate electrode 420 and second gate electrode 425 may comprise materials such as metals or doped oxide semiconductors, such as n-type doped zinc oxide, indium oxide, or tin oxide, including indium-tin oxide (ITO), to name but a few examples, though other materials may be used to form a gate layer and will be understood by one of ordinary skill. Additionally, first gate electrode 420 and second gate electrode 425 may comprise a metal such as Al, Ag, In, Sn, Zn, Ti, Cr, Mo, Au, Pd, Pt, Cu, W, Ni or combinations thereof, or other conductive material. However, it should be noted that claimed subject matter is not limited in this regard. In addition third layer 430 may comprise organic dielectrics such as curable monomers, including UV curable acrylic monomers, UV curable monomers, or thermal curable monomers; acrylic polymers; polymer solutions such as melted polymers or oligomer solutions; poly methyl methacrylate; poly vinylphenol; benzocyclobutene; or one or more polyimides, to name but a few examples. Furthermore, third layer 430 may comprise multiple sub-layers, including one or more inorganic dielectric or organic dielectric layers, though other materials may be used to form a gate insulator layer and will be understood by one of ordinary skill.

With regard to un-patterned oxide layer 440, vacuum deposition processes may include, but are in no way limited to, RF (radio frequency) sputtering, DC sputtering, DC-pulsed sputtering, reactive sputtering, thermal evaporation, electron-beam evaporation, chemical vapor deposition (CVD), or atomic layer deposition (ALD), for example. With further regard to un-patterned oxide layer 440, the oxide material may under some circumstances further comprise combinations of the above listed oxides with other oxides such as lead oxide, copper oxide, silver oxide, and antimony oxide, for example, though other materials may be suitable as well, and of course claimed subject matter is not limited in this regard.

With regard to first source electrode 470 and first drain electrode 475, other materials may be used, such as other doped oxide semiconductors, such as n-type doped zinc oxide, indium oxide, and tin oxide, or metals, such as Al, Ag, In, Sn, Zn, Ti, Cr, Mo, Au, Pd, Pt, Cu, W, Ni, or combinations thereof, to name but a few examples, although again, it should be noted that claimed subject matter is not limited in this regard. With regard to second source electrode 480 and second drain electrode 485, other doped oxide semiconductors, such as n-type doped zinc oxide, indium oxide, and tin oxide, or metals, such as Al, Ag, In, Sn, Zn, Ti, Cr, Mo, Au, Pd, Pt, Cu, W, Ni, or combinations thereof, may be used, to name but a few examples, and again claimed subject matter is not so limited.

Though embodiment 400 has been described above with regard to a particular structure it should be noted that the thin-film transistors may be of any type or structure, including but not limited to, horizontal, vertical, coplanar electrode, staggered electrode, top-gate, bottom-gate, single-gate, and double-gate, to name but a few. In this context, a coplanar electrode configuration may mean a transistor structure where the source and drain electrodes are positioned on the same side of the channel layer as the gate electrode. In this context, a staggered electrode configuration may mean a transistor structure where the source and drain electrodes are positioned on the opposite side of the channel layer as the gate electrode.

The above embodiments are provided merely as examples and claimed subject matter is not so limited. Though above embodiments are described in terms of one or two transistors the claimed subject matter is not so limited. One skilled in the art, in light of this disclosure, could make embodiments having as many transistors as necessary to form a wide variety of semiconductor devices or circuits. It will, of course, also be understood that, although particular embodiments have just been described, the claimed subject matter is not limited in scope to a particular embodiment or implementation.

In the preceding description, various aspects of the claimed subject matter have been described. For purposes of explanation, specific numbers, systems or configurations were set forth to provide a thorough understanding of claimed subject matter. However, it should be apparent to one of ordinary skill having the benefit of this disclosure that claimed subject matter may be practiced without the specific details. In other instances, features or methods that would be understood by one of ordinary skill were omitted or simplified so as not to obscure claimed subject matter. While certain features have been illustrated or described herein, many modifications, substitutions, changes or equivalents will now occur to one of ordinary skill. It is, therefore, to be understood that the appended claims are intended to cover all such modifications or changes as fall within the true spirit of claimed subject matter.

1. An apparatus comprising:
a thin-film device having an active region formed by laser annealing a selected portion of a blanket coated material.

2. The apparatus of claim 1, wherein said blanket coated material comprises a blanket coated semiconductor material.

3. The apparatus of claim 2, wherein said blanket coated semiconductor material comprises an oxide material.

4. The apparatus of claim 3, wherein said oxide material comprises at least one of zinc oxide, tin oxide, indium oxide, cadmium oxide, gallium oxide, zinc tin oxide, zinc indium oxide, tin indium oxide, and combinations thereof.

5. The apparatus of claim 3, wherein said oxide material comprises zinc tin oxide, with a zinc:tin atomic ratio between approximately 1:4 and approximately 4:1.

6. The apparatus of claim 2, wherein said blanket coated semiconductor material is formed by sputtering an oxide material over at least a portion of a substrate

7. The apparatus of claim 6, wherein said sputtering comprises RF, DC, or DC-pulsed sputtering.

8. The apparatus of claim 6, wherein said sputtering comprises sputtering from one or more oxide targets.

9. The apparatus of claim 6, wherein said sputtering comprises reactive sputtering.

10. The apparatus of claim 9, wherein said reactive sputtering comprises reactively sputtering from one or more metallic targets.

11. The apparatus of claim 6, wherein said sputtering comprises sputtering at a substrate temperature less than approximately 100 C.

12. The apparatus of claim 2, wherein said laser annealing comprises applying a laser beam on the selected portion of the blanket coated semiconductor material.

13. The apparatus of claim 12, wherein said laser beam is formed by selectively controlling a laser.

14. The apparatus of claim 13, wherein said laser comprises a first laser.

15. The apparatus of claim 14, wherein selectively controlling said laser comprises providing a first signal to said first laser such that a first laser beam having a first power is produced for a first duration.

16. The apparatus of claim 15, wherein said laser further comprises a second laser.

17. The apparatus of claim 16, wherein selectively controlling said laser further comprises providing a second signal to said second laser such that a second laser beam having a second power is produced for a second duration.

18. The apparatus of claim 17, wherein selectively controlling said laser further comprises providing a plurality of signals to said first laser or said second laser such that a plurality of laser pulses are generated.

19. The apparatus of claim 13, wherein said laser comprises an excimer laser.

20. The apparatus of claim 19, wherein said excimer laser is operable to generate a laser beam having a wavelength of approximately 193-337 nm.

21. The apparatus of claim 2, wherein said blanket coated semiconductor material comprises a material that is substantially insulating in regions outside the laser annealed selected portions.

22. The apparatus of claim 21, wherein the substantially insulating regions of said blanket coated semiconductor material substantially hinder lateral current flow through said substantially insulating regions of said blanket coated semiconductor material.

23. A composition of matter comprising:
a blanket coated oxide material, and
a thin-film transistor channel region formed by selectively annealing a selected portion of said blanket coated oxide material.

24. The composition of matter of claim 23, wherein said blanket coated oxide material comprises at least one of zinc oxide, tin oxide, indium oxide, cadmium oxide, gallium oxide, zinc tin oxide, zinc indium oxide, tin indium oxide, and combinations thereof.

25. The composition of matter of claim 23, wherein the selectively annealed selected portion comprises a laser annealed selected portion of said blanket coated oxide material.

26. The composition of matter of claim 25, wherein said laser annealed selected portion of said blanket coated oxide material comprises a selected portion of said oxide material having been exposed to a plurality of laser beams.

27. The composition of matter of claim 26, wherein said plurality of laser beams comprise at least one first laser beam generated by a first laser.

28. The composition of matter of claim 27, wherein said plurality of laser beams further comprise at least one second laser beam generated by a second laser.

29. The composition of matter of claim 27, wherein said first laser comprises an excimer laser.

30. The composition of matter of claim 25, and further comprising a substrate, wherein said blanket coated oxide material has been vacuum deposited over at least a portion of said substrate.

31. The composition of matter of claim 30, wherein vacuum deposited comprises sputtering said blanket coated oxide material over said substrate.

32. The composition of matter of claim 25, and further comprising a source electrode and a drain electrode.

33. The composition of matter of claim 32, wherein said source electrode, said drain electrode, and said channel region are configured such that said source electrode, said drain electrode, and said channel region are operable to function as a transistor.

34. The composition of matter of claim 33, wherein said source electrode and said drain electrode comprise indium-tin oxide vacuum deposited over at least a portion of said blanket coated oxide material.

35. An apparatus comprising:
a thin-film transistor comprising a blanket coated oxide material, said blanket coated oxide material comprising a laser annealed active region.

36. The apparatus of claim 35, wherein said laser annealed active region comprises a channel portion of a transistor.

37. The apparatus of claim 36, wherein said blanket coated oxide material comprises at least one of zinc oxide, tin oxide, indium oxide, cadmium oxide, gallium oxide, zinc tin oxide, zinc indium oxide, and combinations thereof.

38. The apparatus of claim 36, wherein said laser annealed active region is formed by selectively exposing a first portion of said blanket coated oxide material to a first laser beam.

39. The apparatus of claim 38, wherein said laser annealed active region is formed by further exposing said first portion of said blanket coated oxide material to a second laser beam.

40. The apparatus of claim 36, wherein said thin-film transistor further comprises a drain electrode and a source electrode positioned such that said laser annealed active region is operable to function as a channel.

41. The apparatus of claim 40, wherein said source electrode and said drain electrode comprise indium-tin oxide vacuum deposited over at least a portion of said blanket coated oxide material.

42. The apparatus of claim 40, wherein said blanket coated oxide material further comprises a non-laser annealed region.

43. The apparatus of claim 42, wherein said non-laser annealed region has properties such that lateral current flow through said non-laser annealed region is substantially precluded.

44. An apparatus comprising:
a un-patterned oxide material comprising a first selectively annealed portion and a second selectively annealed portion;
a first transistor comprising a first active region comprising said first selectively annealed portion of said un-patterned oxide material; and
a second transistor comprising a second active region comprising said second selectively annealed portion of said un-patterned oxide material.

45. The apparatus of claim 44, wherein said first active region and said second active region comprise thin-film transistor channels.

46. The apparatus of claim 45, wherein said un-patterned oxide material comprises at least one of zinc oxide, indium oxide, tin oxide, cadmium oxide, gallium oxide, zinc tin oxide, zinc indium oxide, and combinations thereof.

47. The apparatus of claim 45, wherein said un-patterned oxide material comprises a vacuum deposited oxide material.

48. The apparatus of claim 47, wherein said vacuum deposited oxide material comprises a sputtered oxide material.

49. The apparatus of claim 46, wherein said first transistor further comprises a first source electrode, a first drain electrode, or a first gate electrode.

50. The apparatus of claim 49, wherein said second transistor further comprises a second source electrode, a second drain electrode, or a second gate electrode.

51. The apparatus of claim 49, wherein said first source electrode and said first drain electrode comprise vacuum deposited indium-tin oxide.

52. The apparatus of claim 50, wherein said second source electrode and said second drain electrode comprise vacuum deposited indium-tin oxide.

53. The apparatus of claim 46, wherein said first selectively annealed portion of said un-patterned oxide material comprises a laser annealed first selected portion of said un-patterned oxide material and said second selectively annealed portion of said un-patterned oxide material comprises a laser annealed second selected portion of said un-patterned oxide material.

54. The apparatus of claim 53, wherein said un-patterned oxide material further comprises a non-laser annealed portion.

55. The apparatus of claim 54, wherein said non-laser annealed portion substantially hinders current leakage between said first transistor and said second transistor.

56. The apparatus of claim 50, wherein said un-patterned oxide material further comprises a non-laser annealed portion.

57. The apparatus of claim 56, wherein said non-annealed portion substantially hinders current leakage between said first transistor and said second transistor.

58. A method comprising:
forming an un-patterned material layer; and
selectively annealing a first portion of said un-patterned material layer to form a semiconductive active region

59. The method of claim 58, wherein said un-patterned material layer comprises and un-patterned oxide layer.

60. The method of claim 59, and further comprising:
forming a source electrode and a drain electrode, wherein said source electrode and said drain electrode are positioned such that the selectively annealed portion of said un-patterned oxide layer is operable to function as a channel region.

61. The method of claim 60, wherein selectively annealing a first portion of said un-patterned oxide layer comprises applying a first laser pulse to a selected portion of said un-patterned oxide layer.

62. The method of claim 61, wherein selectively annealing a first portion of said un-patterned oxide layer further comprises applying a second laser pulse to said selected portion of said un-patterned oxide layer.

63. The method of claim 62, wherein selectively annealing a first portion of said un-patterned oxide layer further comprises generating said first laser pulse with a first laser.

64. The method of claim 63, wherein selectively annealing a first portion of said un-patterned oxide layer further comprises generating said second laser pulse with a second laser.

65. The method of claim 64, wherein generating said first laser pulse comprises selectively applying a first signal to said first laser.

66. The method of claim 65, wherein generating said second laser pulse comprises selectively applying a second signal to said second laser.

67. The method of claim 65, wherein said first laser comprises an excimer laser.

68. The method of claim 60, wherein forming said un-patterned oxide material comprises vacuum depositing the oxide material.

69. The method of claim 68, wherein vacuum depositing the oxide material comprises sputtering the oxide material.

70. The method of claim 69, wherein said sputtering comprises RF, DC, DC-pulsed, or reactive sputtering.

71. The method of claim 69, wherein the oxide material comprises at least one of zinc oxide, indium oxide, tin oxide, zinc tin oxide, zinc indium oxide, and combinations thereof.

72. The method of claim 69, wherein forming said source electrode and said drain electrode comprises vacuum depositing indium-tin oxide over at least a portion of said un-patterned oxide layer.

73. The method of claim 72, wherein vacuum depositing indium-tin oxide comprises sputtering indium-tin oxide.

74. An article comprising: a storage media having stored thereon instructions that when executed result in:
forming an un-patterned oxide layer; and
selectively annealing a first portion of said un-patterned material layer to form a semiconductive active region

75. The article of claim 74, wherein said un-patterned material layer comprises and un-patterned oxide layer.

76. The article of claim 75, and further comprising:
forming a source electrode and a drain electrode, wherein said source electrode and said drain electrode are positioned such that the selectively annealed portion of said un-patterned oxide layer is operable to function as a channel region.

77. The article of claim 76, wherein selectively annealing a first portion of said un-patterned oxide layer comprises applying a first laser pulse to a selected portion of said un-patterned oxide layer.

78. The article of claim 77, wherein selectively annealing a first portion of said un-patterned oxide layer further comprises applying a second laser pulse to said selected portion of said un-patterned oxide layer.

79. The article of claim 78, wherein said instructions when executed further result in generating said first laser pulse and said second laser pulse.

80. The article of claim 79, wherein generating said first laser pulse comprises selectively applying a first signal to a first laser.

81. The article of claim 80, wherein generating said second laser pulse comprises selectively applying a second signal to a second laser.

82. The article of claim 80, wherein said first laser comprises an excimer laser.

83. The article of claim 77, wherein forming said un-patterned oxide layer comprises vacuum depositing the oxide material.

84. The article of claim 83, wherein vacuum depositing the oxide material comprises sputtering the oxide material.

85. The article of claim 84, wherein the oxide material comprises zinc oxide, tin oxide, indium oxide, cadmium oxide, gallium oxide, zinc indium oxide, zinc tin oxide, and combinations thereof.

86. The article of claim 85, wherein forming said source electrode and said drain electrode comprises vacuum depositing indium-tin oxide over at least a portion of said un-patterned oxide layer.

87. The article of claim 86, wherein vacuum depositing indium-tin oxide comprises sputtering indium-tin oxide.

88. A system comprising:
a semiconductor device comprising a plurality of transistors, wherein said plurality of transistors comprises at least a plurality of thin-film transistors comprising an active region comprising a selectively annealed portion of a blanket-coated oxide material.

89. The system of claim 88, wherein said selectively annealed active region comprises a laser annealed selected portion of said blanket-coated oxide material.

90. The system of claim 89, wherein said laser annealed selected portion of said blanket-coated oxide material comprises a selected portion of said blanket-coated oxide material that has been exposed to a first laser beam.

91. The system of claim 89, wherein each of said plurality of thin-film transistors further comprises a gate electrode, a source electrode, or a drain electrode.

92. The system of claim 89, wherein each selectively annealed active region is operable to function as a channel region in conjunction with a respective gate electrode, source electrode, or drain electrode.

93. The system of claim 92, wherein said blanket-coated oxide material comprises an oxide material vacuum deposited onto at least a portion of said semiconductor device.

94. The system of claim 92, wherein said blanket-coated oxide material comprises an oxide material sputtered over at least a portion of said semiconductor device.

95. The system of claim 92, wherein said blanket-coated oxide material comprises an oxide material RF sputtered, DC sputtered, or DC-pulse sputtered over at least a portion of said semiconductor device.

96. The system of claim 92, wherein said blanket coated oxide material comprises at least one of zinc oxide, tin oxide, indium oxide, cadmium oxide, gallium oxide, zinc indium oxide, zinc tin oxide, and combinations thereof.

97. The system of claim 92, wherein said blanket-coated oxide material further comprises a non-selectively annealed region.

98. The system of claim 97, wherein said non-selectively annealed region has properties such that lateral current flow through said non-selectively annealed region is substantially precluded.

99. The system of claim 98, wherein said semiconductor device comprises an active matrix display.
